(19) United States
(12) Patent Application Publication
(10) Pub. No.: US 2006/0254051 A1
(43) Pub. Date: Nov. 16, 2006

(54) Method for the space-saving installation of electrical wiring

(75) Inventors: Jörg Huber, (US); Siegfried Schreiber, Althengstett (DE); Jürgen Söllner, Frankfurt/Main (DE)

Correspondence Address: FITCH, EVEN, TABIN & FLANNERY, P. O. BOX 65973, WASHINGTON, DC, 20035, US

(73) Assignee: DAIMLERCHRYSLER AG, STUTTGART (DE)

(21) Appl. No.: 10/563,426

(22) PCT Filed: Jun. 29, 2004
(86) PCT No.: PCT/EP04/07017

§ 371 Date: Apr. 5, 2006

(30) Foreign Application Priority Data
Jul. 5, 2003 (DE) 103 30 448.7

(51) Int. Cl. H05K 3/10

(52) U.S. Cl. 29/846; 29/868

(57) ABSTRACT

In a method for the space-saving arrangement of conductor tracks (5-8) on device components (12), in particular on the body parts of motor vehicles, an insulating base layer (2) is applied to a metallic device component (12). Subsequently, the conductor track material is applied in a number of parallel tracks and activated. Subsequently, an electrically insulating protective layer (3) is arranged on the conductor tracks (5-8).

The invention relates to a method for the space-saving installation of electrical wiring in or on a device.

For the connection of various items of electrical and electronic equipment that are fitted in a motor vehicle, it is known to use cable harnesses which comprise a connecting part, made in the form of a strip and having a number of cables in the form of wires, and a number of branches. The cable harness is accommodated in intermediate spaces that are formed between the vehicle frame or the basic body of the vehicle and other body parts, and is fastened at suitable points by fastening means. Since an ever-increasing number of loads in a motor vehicle have to be supplied with control signals and electrical power, the cabling is becoming more and more complicated. It is therefore intended wherever possible to find an alternative to the cable harnesses, or at least reduce their size.

The object of the invention is therefore to simplify the installation of wiring, with a reduced space requirement.

This object is achieved by a method of the type mentioned at the beginning in which a first electrically insulating layer is applied to a device component, one or more conductor tracks are applied in one or more layers to the insulating layer and the conductor track or conductor tracks is or are covered by a second insulating layer. The successive conductor-track and insulating layers form a stack of layers.

In particular in the case of motor vehicles, the method according to the invention makes it possible to apply conductor tracks directly to body parts and protect them both above and below by insulating layers. The laborious laying of cables, in particular in places where access is difficult, is rendered superfluous. The method according to the invention allows costs to be saved, assembly to be simplified and possible sources of error to be reduced. It is particularly advantageous that the body parts themselves can be used as the carrier of the stack of layers. The fact that the stack of layers, comprising insulating layers and conductor tracks, is applied directly to the body parts and adapted to them means that the electrical wiring can be arranged in a particularly space-saving way. Device components that come into consideration in particular are interior surfaces of doors, transverse members of seats, transverse members of the driver's area, the rear lid or tailgate.

In the stack of layers, the individual conductor tracks preferably run parallel to one another and insulated from one another. Through the conductor tracks, loads can be supplied with electrical energy but also with signals. It is consequently possible for signal and supply lines to run alongside one another in the same stack of layers or in the same stack of conductor tracks.

If the conductor tracks are applied in a number of layers at successive times and spatially one on top of the other, a greater thickness, and consequently greater cross section, of the electrical wiring lines can be made available with the same area coverage for the transmission of greater current intensities. The individual conductor tracks may have different widths and in this way be configured for their respective intended use.

All the method steps can be applied separately one after the other or in one operation by automatically controlled application devices arranged one after the other. In particular, the method is suitable for being carried out by industrial robots.

In the case of a particularly preferred variant of the method, a number of conductor-track layers and electrically insulating layers are applied alternately. This produces a greater number of electrical wiring lines, with the same area coverage, for a greater number of signals or supply currents. The layers can be applied in one operation.

It is particularly preferred if a first shielding layer is applied on the side of the stack of layers that is facing away from the device component. This is advantageous in particular in the case of wiring for a radio, microphone, GPS or telephone, to ensure satisfactory operation. Electrically conductive layers, which shield the conductor tracks against electromagnetic fields, are preferably provided as shielding layers.

If an electrically insulating material, such as plastic for example, is provided as the carrier material, an electrically conductive layer may be applied as the lowermost layer, on which the first insulating layer is then arranged. Such an electrically conductive layer likewise serves for shielding with respect to electromagnetic fields. The electrically insulating carrier material may be the device component itself or a sheathing or coating of the device component.

The layers are preferably applied by dispensing, printing, spraying, suspension-jetting, vapor deposition, in particular chemical vapor deposition, precipitation, through porous materials or by means of rollers. In particular if the layers to be applied are in the form of powder, a thick-film or thin-film paste, a suspension, emulsion, solution or vapor, these layers can be applied in the aforementioned way. In the case of suspension-jetting, in particular of the conductor tracks, extremely fine droplets or particles of a liquid, a suspension or a volatile solid material can be propelled onto the carrier by spontaneous vapor or gas generation. If the layers are sprayed on, this may take place with a spray head or with nozzles. In this case, single-hole or multi-hole nozzles may be provided. Liquid layer precursors can be applied through porous substances with the application devices in direct contact with the carrier or with the layer onto which application is to take place. It is also possible for liquid layer precursors to be applied by means of a rolling ball or by means of a rolling roller. In particular, machine tools with a number of parallel porous pins or rolling balls or rolling rollers are conceivable for the automated application of the layers or conductor tracks.

Preferably, after their application, the layers are subsequently treated and/or activated and/or conditioned. This may take place by firing, blasting with hot air, irradiation with UV light, visible light or infrared light, passing a high current through them, vacuum suction or x-ray irradiation. These measures have the effect of increasing the stability of the layers. In particular, the conductor tracks may be applied in a readily deformable preform and be subsequently activated and made conductive. The application and activation of the layers or each individual layer may be performed at short time intervals by tools that are coupled to one another.

The electrically conductive layers, that is in particular the metallic conductor tracks and shielding layers, may advantageously be galvanically reinforced. The galvanic reinforcement makes the transmission of greater current intensities possible.

In the case of a variant of the method, it may be provided that the conductor tracks are applied individually, in particular by means of delivery tubes, or over a large area by using masks. In the case of individual delivery tubes, they may be rigidly connected to the application device or a delivery head of the application device or be guided contactlessly or with slight pressure exertion and with controlled adaptation of their length and direction in dependence on the respectively recorded distance from the surface of the carrier. The delivery tubes may be arranged on delivery heads. A number of delivery tubes may be provided for the simultaneous application of a number of parallel conductor tracks or only one delivery tube for the sequential application of the conductor tracks. The application devices for applying the layers may be formed in such a way that they are flat on the underside or adapted to the shape of the carrier or device part to be coated. The tools or delivery heads for carrying out the method and for producing stacks of layers and their use for this purpose are regarded as an independent invention.

The conductor tracks of a conductor-track layer may be applied simultaneously and parallel to one another from a multiple delivery head or from a number of delivery heads arranged next to one another. In this case, the delivery head or heads and the surface onto which material is to be applied are moved in relation to one another. Either the delivery head or heads is/are fixed in place and the device component moves, or vice versa. In particular, it may be provided that the delivery head or heads perform(s) a straight or bent longitudinal movement and is/are in this case arranged at a small height above the surface onto which material is to be applied, or touch(es) it, so that elongated conductor tracks are produced.

The conductor tracks can be applied particularly quickly and easily if they are arranged in films which are adhesively attached or laminated onto the insulating layer.

It may be provided that the electrical conductor tracks are applied in a form which cannot be used immediately and are activated, i.e. are transformed into a firmly adhering electrically conductive form, in a further working step shortly after their application.

In one embodiment of the method, the device component may be kept at a predetermined temperature during the application of the layers. In particular, the device component or the carrier may be heated, cooled or kept at room temperature. In particular, different temperatures may be provided for different layers. As a result, optimum application of the individual layers is ensured.

In particular when powders are used as layer precursors, it is advantageous to apply a primer before the application of the layer. The primer may take the form of a liquid or adhesion-producing material. Surface regions, particular regions in which the conductor tracks are to be arranged, may be defined over the primer, in order that the powder adheres only to these specific surface regions.

At least two, in particular all, method steps for producing the stack of layers are advantageously performed at time intervals one after the other or synchronously. Application at short time intervals or synchronously can be carried out by coupled tools.

The invention also relates to a stack of layers which is installed on a device or a device component in such a way that it is in surface contact and adapted to its shape, the stack of layers having a number of conductor tracks, which run parallel to one another in a conductor-track layer and are embedded between a first and a second electrically insulating layer. By means of such a stack of layers which contains electrically conducting conductor tracks, devices, in particular motor vehicles, can be wired in a particularly easy and space-saving manner, since the stack of layers follows the geometrical shapes of the device components. According to the invention, in this way current or signal conduction without cables is made possible.

The stack of layers may have a number of alternating electrically insulating layers and conductor-track layers. If there is a small space requirement, consequently a multiplicity of conductor tracks can be routed parallel to one another.

To avoid disturbances to the loads to which the conductor tracks lead, a first shielding layer may be provided on the side of the stack of layers that is facing away from the device component or the device. This first shielding layer may represent the uppermost layer of the stack of layers or be covered by an electrically insulating layer.

If the stack of layers is to be installed on an electrically insulating device component, a second shielding layer may be applied as the first layer on the device component, in order likewise to ensure shielding of the conductor tracks.

Coatings, plastics, coloring mixtures, adhesives, adhesion promoters, inorganic or organometallic materials may be provided as preferred electrically insulating layers. The electrically insulating layers and/or the shielding layers and/or the conductor-track layers can be applied particularly quickly and easily if they take the form of films. Taking the form of films also ensures that they adapt themselves particularly well to the contours of the device component, that is the carrier on which the stack of layers is installed.

The conductor tracks may consist of metal, in particular copper or silver, electrically conductive semimetal or nonmetal.

Exemplary embodiments of the invention are explained in more detail on the basis of the drawing, in which:

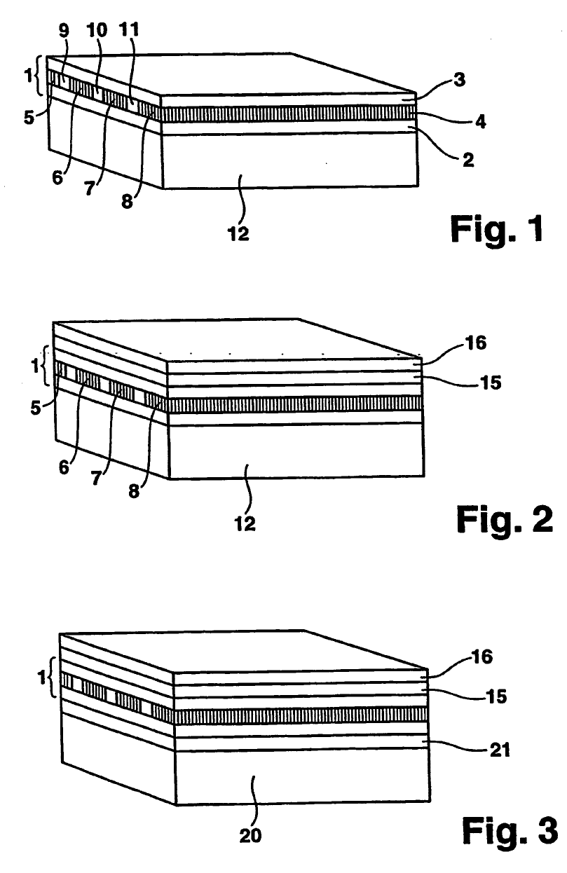

FIG. 1 shows a perspective view of a stack of layers according to the invention, which is installed on an electrically conducting device component;

FIG. 2 shows a perspective view of a stack of layers with shielding;

FIG. 3 shows a perspective view of a stack of layers which is applied to an electrically insulating carrier;

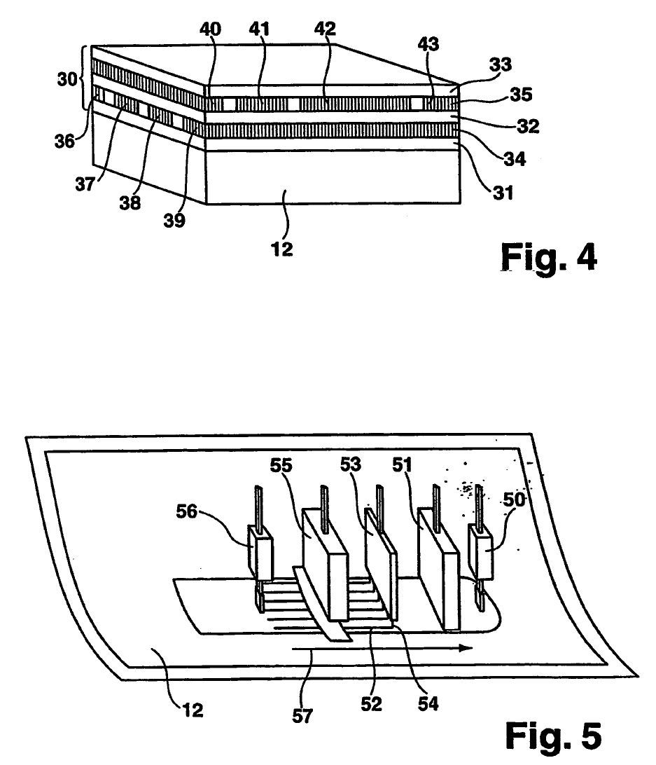

FIG. 4 shows a perspective view of a stack of layers with a number of conductor-track layers;

FIG. 5 shows a schematic representation of the method for producing a stack of layers.

The stack of layers 1 represented in FIG. 1 comprises a first insulating layer 2 and a second insulating layer 3, in between which the conductor-track layer 4 is embedded. The conductor-track layer 4 has a number of conductor tracks 5, 6, 7, 8, running parallel to one another. The conductor tracks 5-8 are electrically insulated in relation to one another, the intermediate spaces 9, 10, 11 containing air in the exemplary embodiment, but may contain any desired electrically insulating material. The conductor tracks 5-8 are of different widths and are in this way designed for different current intensities or signals. The stack of layers 1 is applied and fastened directly to a device component 12, the device component 12 being an electrically conducting carrier. The arrangement according to FIG. 1 can be produced in particular by firstly the first insulating layer 2 being applied to the device component 12. After the drying of the first insulating layer 2, the conductor-track layer 4 with the conductor tracks 5-8 is applied. The conductor-track layer 4 may be applied in one operation as one layer or in a number of operations in a number of layers. After that, the conductor-track layer 4 or the conductor tracks 5-8 is/are dried and activated. Subsequently, the second electrically insulating layer 3 is sprayed on.

In the case of the representation of FIG. 2, an electrically conductive shielding layer 15, which serves as electromagnetic shielding for the conductor tracks 5-8, is applied to the stack of layers 1. On the shielding layer 15, an electrically insulating layer 16 is in turn applied. The electrically conductive device component 12 serves as electromagnetic shielding of the conductor tracks 5-8 from below.

In the representation of FIG. 3, the stack of layers 1 is applied to an electrically insulating device component 20. To ensure electromagnetic shielding, a second electrically conductive shielding layer 21 is arranged between the stack of layers 1 and the device component 20. To ensure complete shielding against electromagnetic rays, arranged on the stack of layers 1 is the first electrically conductive shielding layer 15, on which in turn the electrically insulating layer 16 is provided.

FIG. 4 shows a stack of layers 30, which is arranged on an electrically conductive device component 12. The stack of layers comprises three electrically insulating layers 31, 32, 33 alternating with conductor-track layers 34, 35. The first conductor-track layer 34 comprises four conductor tracks 36-39, which are insulated from one another and run parallel next to one another, and the conductor-track layer 35 comprises four conductor tracks 40-43, which are insulated from one another and run parallel next to one another. In the exemplary embodiment, the conductor tracks 40-43 run perpendicularly in relation to the conductor tracks 36-39. In principle, however, any desired arrangement of the conductor tracks 40-43 is possible with respect to the conductor tracks 36-39 running in another conductor-track layer 34.

The method for producing a stack of layers on a device component is represented in a greatly schematized form in FIG. 5. Firstly, an electrically insulating layer is applied to the electrically conducting device component 12 by a first delivery head 50. The electrically insulating layer is subsequently dried by a drying device 51. This is followed by the application of the conductor tracks 52 by a multiple delivery head 53, which in each case has a delivery tube 54 for the simultaneous application of the conductor tracks 52. The conductor tracks 52 are dried by a second drying unit 55 and activated. After that, a further insulating layer is sprayed on by means of the delivery head 56. The first delivery head 50, the drying device 51, the multiple delivery head 53, the second drying unit 55 and the application head 56 may be independent tools, which may be coupled to one another or they may form part of a single application tool. During operation, the first delivery head 50, the drying unit 51, the multiple delivery head 53, the second drying unit 55 and the application head 56 move in the direction of the arrow 57 along the fixed device component 12.

In the case of a method for the space-saving arrangement of conductor tracks (5-8) on device components (12), in particular on body parts of motor vehicles, an insulating base layer (2) is applied to a metallic device component (12). Subsequently, the conductor track material is applied in a number of parallel tracks and activated. Subsequently, an electrically insulating protective layer (3) is arranged on the conductor tracks (5-8).

1. A method for the space-saving installation of electrical wiring in or on a device, characterized in that, to produce a stack of layers, a first electrically insulating layer (2, 31) is applied to a device component (12, 20), one or more conductor tracks (5-8, 36-39) are applied in one or more conductor-track layers (4, 34) to the insulating layer (2, 31) and the conductor track or conductor tracks (5-8, 36-39) is or are covered by a second insulating layer (3, 32).

2. The method as claimed in claim 1, characterized in that a number of conductor-track layers (34, 35) and electrically insulating layers (31-33) are applied alternately to form a stack of layers (1, 30).

3. The method as claimed in one of the preceding claims, characterized in that a first shielding layer (15) is applied to the stack of layers (1, 30), comprising conductor-track layers (4, 34, 35) and electrically insulating layers (2, 3, 31-33), on the side that is facing away from the device component (12, 20).

4. The method as claimed in one of the preceding claims, characterized in that, before the application of the first electrically insulating layer (2, 31), a second electrically conducting shielding layer (21) is applied to the device component (20).

5. The method as claimed in one of the preceding claims, characterized in that the layers (2, 3, 4, 15, 16, 21, 31-35) are applied by dispensing, printing, spraying, suspension-jetting, vapor deposition, in particular chemical vapor deposition (CVD), precipitation, through porous materials or by means of rollers.

6. The method as claimed in one of the preceding claims, characterized in that, after their application, the layers (2, 3, 4, 15, 16, 21, 31-35) are subsequently treated and/or activated and/or conditioned.

7. The method as claimed in one of the preceding claims, characterized in that the electrically conductive layers (4, 15, 21, 34, 35) are galvanically reinforced.

8. The method as claimed in one of the preceding claims, characterized in that the conductor tracks (5-8, 36-43) are applied individually, in particular by means of delivery tubes (54), or over a large area by using masks.

9. The method as claimed in one of the preceding claims, characterized in that the conductor tracks (5-8, 36-39) of a conductor-track layer (4, 34, 35) are applied simultaneously and parallel to one another from a multiple delivery head (53) or from a number of delivery heads arranged next to one another.

10. The method as claimed in one of the preceding claims, characterized in that a primer is applied before the application of a layer.

11. The method as claimed in one of the preceding claims, characterized in that at least two, in particular all, method steps for producing the stack of layers are advantageously performed at time intervals one after the other or synchronously.

12. The method as claimed in one of claims 1 to 7, characterized in that the conductor tracks (5-8, 36-43) are arranged in films which are adhesively attached or laminated on.

13. The method as claimed in one of the preceding claims, characterized in that the device component (12, 20) is kept at a predetermined temperature during the application of the layers.

14. A stack of layers (1, 30), which is installed on a device or a device component (12, 20) in such a way that it is in surface contact and adapted to its shape, the stack of layers (1, 30) having a number of conductor tracks (5-8, 36-43), which run parallel to one another in a conductor-track layer (4, 34, 35) and are embedded between a first and a second electrically insulating layer (2, 3, 31-33).

15. The stack of layers as claimed in claim 14, characterized in that a number of electrically insulating layers (31-33) and conductor-track layers (34, 35) are stacked alternately.

16. The stack of layers as claimed in either of claims 14 and 15, characterized in that a first shielding layer (15) is applied on the side of the stack of layers (1, 30) that is facing away from the device component (12, 20).

17. The stack of layers as claimed in one of claims 14 to 16, characterized in that a second shielding layer (21) is provided as the lowermost layer.

18. The stack of layers as claimed in one of claims 14 to 17, characterized in that the electrically insulating layers (2, 3, 16, 31-33) take the form of a coating, plastic, coloring mixture, adhesive, adhesion promoter, inorganic or organometallic material.

19. The stack of layers as claimed in one of claims 14 to 18, characterized in that the electrically insulating layers (2, 3, 16, 31-33) and/or shielding layers (15, 21) and/or the conductor-track layers (4, 34, 35) take the form of films.

20. The stack of layers as claimed in one of claims 14 to 19, characterized in that the conductor tracks (5-8, 36-43) consist of metal, in particular copper or silver, electrically conductive semimetal or nonmetal.
